(19) United States
(12) Patent Application Publication
(10) Pub. No.: US 2024/0276650 A1
(43) Pub. Date: Aug. 15, 2024

(54) CIRCUIT BOARD AND MANUFACTURING METHOD THEREOF

(71) Applicant: TONG HSING ELECTRONIC INDUSTRIES, LTD., TAIPEI CITY (TW)

(72) Inventors: Yu-Hsien LIAO, TAIPEI CITY (TW); Shih-Han WU, TAIPEI CITY (TW); Jhih-Wei LAI, TAIPEI CITY (TW); Jian-Yu SHIH, TAIPEI CITY (TW); Ming-Yen PAN, TAIPEI CITY (TW)

(21) Appl. No.: 18/323,856

(22) Filed: May 25, 2023

(30) Foreign Application Priority Data
Feb. 9, 2023 (TW) 112104531

(51) Int. Cl. H05K 3/30; H05K 1/03; H05K 1/09; H05K 3/14; H05K 3/38; H05K 3/44

(52) U.S. Cl. CPC H05K 3/305; H05K 1/0306; H05K 1/09; H05K 3/146; H05K 3/386; H05K 3/445; H05K 2203/1338

(57) ABSTRACT

A manufacturing method of a circuit board. The manufacturing method includes: providing a first substrate; forming an opening on the first substrate; disposing a second substrate, which has a plurality of through holes in the opening; forming an adhesive layer between the first substrate and the second substrate; forming a bonding layer on the first substrate and the second substrate; forming a metal layer on the bonding layer; and patterning the metal layer to form a circuit layer. A circuit board is also disclosed in the disclosure.

### BACKGROUND OF THE DISCLOSURE

### Technical Field

The disclosure relates to a circuit board, particularly relates to a circuit board and a manufacturing method thereof.

### Description of Related Art

Following the development of technology, the requirement to the circuit board is also increased accordingly. In the related art, the ceramic block is generally embedded in the circuit board for increasing the heat dissipation efficiency of the circuit board. Specifically, after the ceramic block is embedded into the substrate, the adhesive layer is disposed into the gap between the ceramic block and the substrate to implement the arrangement of the ceramic in the circuit board.

However, in the related art, when it is desired to dispose the ceramic block into the substrate, the connecting metal layer is already formed on the ceramic block and the substrate, respectively. Thus, the connecting metal layer disposed on the ceramic block and the connecting metal layer disposed on the substrate may not be coplanar with each other. This may cause deviation of the circuit layer which is to be disposed in the following process, which may further cause reliability problems.

Therefore, how to provide a circuit board and a manufacturing method thereof for increasing the reliability is the tendency that needs to be developed.

### SUMMARY OF THE DISCLOSURE

In order to achieve the aforementioned purpose, the disclosure provides a circuit board and a manufacturing method thereof, which may increase reliability.

The disclosure provides a manufacturing method of a circuit board. The manufacturing method includes: providing a first substrate; forming an opening in the first substrate; disposing a second substrate, which has multiple through holes in the opening; forming an adhesive layer between the first substrate and the second substrate; forming a bonding layer on the first substrate and the second substrate; forming a metal layer on the bonding layer; and patterning the metal layer to form a circuit layer.

In some embodiments, the disposition of the second substrate in the opening further includes: after forming the through holes in the second substrate, disposing the second substrate in the opening.

In some embodiments, the disposition of the second substrate in the opening further includes: after disposing the second substrate in the opening, forming the through holes in the second substrate.

In some embodiments, the formation of the bonding layer on the first substrate and the second substrate further includes: coplanarly forming the bonding layer on the first substrate and the second substrate.

In some embodiments, the coplanar formation of the bonding layer on the first substrate and the second substrate further includes: forming, by a physical vapor deposition (PVD) process, the bonding layer on the first substrate and the second substrate.

In some embodiments, the coplanar formation of the bonding layer on the first substrate and the second substrate further includes: forming, by a chemical vapor deposition (CVD) process or a chemical plating (or electroless plating) process, the bonding layer on the first substrate and the second substrate.

In some embodiments, the provision of the first substrate further includes: forming a redistribution layer on the first substrate.

In some embodiments, the formation of the metal layer on the bonding layer further includes: forming, by a chemical plating process, the metal layer on the bonding layer.

The disclosure provides a manufacturing method of a circuit board. The manufacturing method includes: providing a substrate; forming a redistribution layer on the substrate; forming an opening in the substrate; disposing a ceramic substrate, which has a plurality of through holes, in the opening; forming an adhesive layer between the substrate and the ceramic substrate; forming a bonding layer on the substrate and the ceramic substrate; forming a metal layer on the bonding layer; and patterning the metal layer to form a circuit layer.

In some embodiments, the disposition of the ceramic substrate in the opening further includes: after forming the through holes in the ceramic substrate, disposing the ceramic substrate in the opening.

In some embodiments, the disposition of the ceramic substrate in the opening further includes: after disposing the ceramic substrate in the opening, forming the through holes in the ceramic substrate.

In some embodiments, the formation of the bonding layer on the substrate and the ceramic substrate further includes: coplanarly forming the bonding layer on the substrate and the ceramic substrate.

In some embodiments, the coplanar formation of the bonding layer on the substrate and the ceramic substrate further includes: forming, by a physical vapor deposition (PVD process, the bonding layer on the substrate and the ceramic substrate.

In some embodiments, the coplanar formation of the bonding layer on the substrate and the ceramic substrate further includes: forming, by a chemical vapor deposition (CVD) process or a chemical plating process, the bonding layer on the substrate and the ceramic substrate.

In some embodiments, the formation of the metal layer on the bonding layer further includes: forming, by a chemical plating process, the metal layer on the bonding layer.

The disclosure provides a circuit board. The circuit board includes: a substrate, having an opening; a ceramic substrate, disposed in the opening, and having a plurality of through holes; an adhesive layer, disposed between the substrate and the ceramic substrate; and a circuit layer, disposed on the substrate and the ceramic substrate. The substrate, the ceramic substrate, and the adhesive layer are substantially coplanar with each other.

In some embodiments, the substrate further includes a redistribution layer connected with the circuit layer.

In some embodiments, the circuit board further includes: a bonding layer, disposed between the circuit layer and the substrate and disposed between the circuit layer and the ceramic substrate.

In some embodiments, the bonding layer is coplanarly extended across the substrate, the ceramic substrate, and the adhesive layer.

In some embodiments, the bonding layer is extended to the through holes.

In summary, the circuit board and the manufacturing method thereof in the disclosure is attained by forming the bonding layer, the metal layer on the first substrate (for example, the printed circuit board substrate) and the second substrate (for example, the ceramic substrate), and the adhesive layer, after the first substrate is connected with the second substrate by the adhesive layer. Since the bonding layer and the metal layer are not formed when the first substrate is connected with the second substrate by the adhesive layer, the surfaces (upper surfaces or lower surfaces) of the first substrate, the second substrate, and the adhesive layer are substantially coplanar. As a result, the bonding layer and the metal layer may be coplanarly formed on the first substrate and the second substrate, and the flatness and thickness uniformity of the circuit layer which is patterned subsequentially may be increased so as to improve the reliability of the circuit board of the disclosure. Further, the bonding layer and the metal layer are formed on the first substrate and the second substrate after the two substrates are connected, thus, the manufacturing process steps may be united so as to be carried out in one station without the need of carrying out each process step in different stations, and the total cost may be further decreased.

### BRIEF DESCRIPTION OF THE DRAWINGS

The technical contents of this disclosure will become apparent with the detailed description of embodiments accompanied with the illustration of related drawings as follows. It is intended that the embodiments and drawings disclosed herein are to be considered illustrative rather than restrictive.

FIG. 1 is a flowchart of the first embodiment of the manufacturing method of the circuit board in the disclosure.

FIG. 2A to FIG. 2I are schematic diagrams illustrating the manufacturing of the circuit board in the disclosure.

FIG. 3 is a flowchart of the second embodiment of the manufacturing method of the circuit board in the disclosure.

FIG. 4 is a schematic diagram of a circuit board in the disclosure.

FIG. 5 is a schematic diagram of a circuit board in the disclosure.

### DETAILED DESCRIPTION

The terms, such as “first”, “second”, are used in the description to describe all kinds of element, assembly, area, layer, and/or part, and the element, assembly, area, layer, and/or part are not limited by the terms. The terms may be used to distinguish one of the element, assembly, area, layer, and/or part from the other one. The terms, such as “first”, “second”, used in the description do not implicitly indicate sequence or order unless the indication is clearly represented in the context.

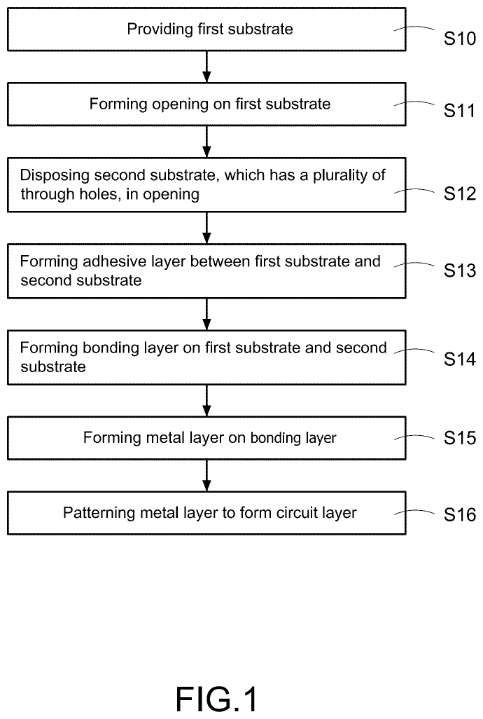

FIG. 1 is a flowchart of the first embodiment of the manufacturing method of the circuit board in the disclosure. As shown in FIG. 1, the first embodiment of the manufacturing method of the circuit board in the disclosure includes the step S10 to the step S16. The step S10 is carried out by providing a first substrate. The step S11 is carried out by forming an opening in the first substrate. The step S12 is carried out by disposing a second substrate, which has a plurality of through holes in the opening. The step S13 is carried out by forming an adhesive layer between the first substrate and the second substrate. The step S14 is carried out by forming a bonding layer on the first substrate and the second substrate. The step S15 is carried out by forming a metal layer on the bonding layer. The step S16 is carried out by patterning the metal layer to form a circuit layer.

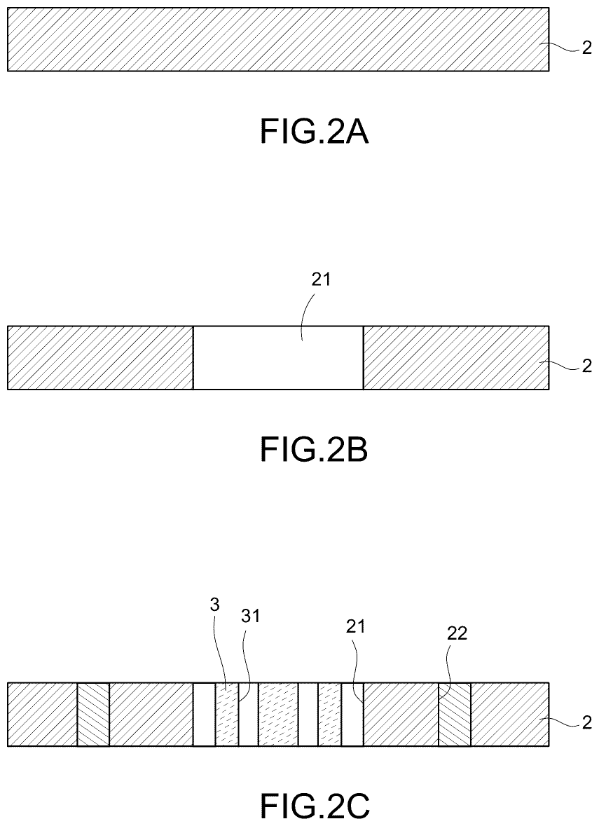

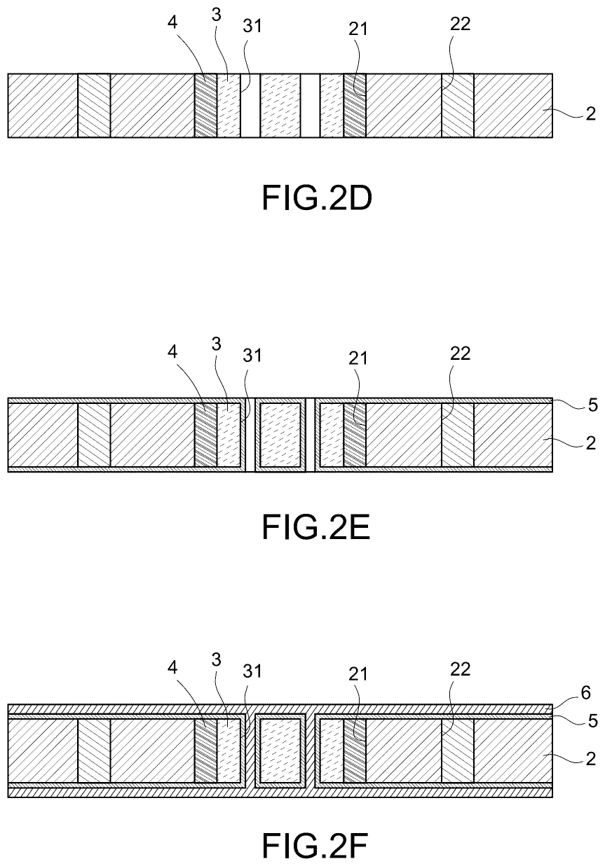

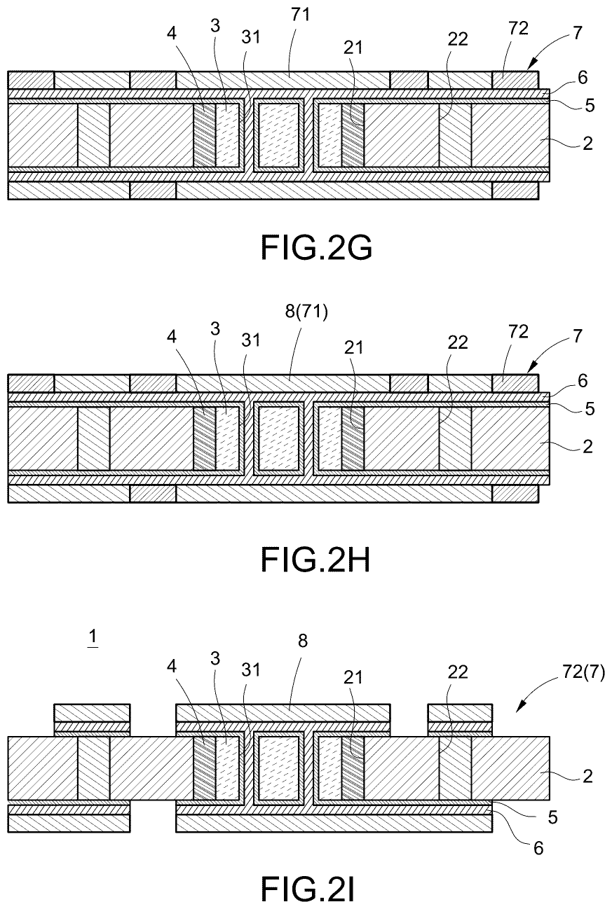

FIG. 2A to FIG. 2I are schematic diagrams illustrating the manufacturing of the circuit board in the disclosure. As shown in FIG. 1 and FIG. 2A, in the step S10, the first substrate 2 is provided. The first substrate 2 is, for example, a printed circuit board substrate, and the material of the printed circuit board substrate may be, for example, FR4 or the other suitable material. It is worth mentioning that, in the step S10, the surface of the first substrate 2 is not covered by the metal layer (the metal layer may be, for example, a copper layer).

As shown in FIG. 1 and FIG. 2B, in the step S11, an opening 21 is formed in the first substrate 2. The opening 21 may be formed in the first substrate 2 by, for example, mechanical machining. The size and shape of the opening 21 is corresponding to the size and shape of the second substrate in the following step. In some embodiments, the size of the opening 21 is slightly greater than the size of the second substrate to facilitate the arrangement of the second substrate in the opening 21.

As shown in FIG. 1 and FIG. 2C, in the step S12, a second substrate 3 is disposed in the opening 21, and the second substrate 3 has a plurality of through holes 31. The second substrate 3 is, for example, a ceramic substrate, and the material of the ceramic substrate may be, for example, Al₂O₃, AlN, Zirconium dioxide (ZrO₂), zirconia toughened alumina (ZTA), SiC, BeO, or Si₃N₄, or the other suitable material. In the embodiment, the through holes 31 are firstly formed in the second substrate 3, and then the second substrate 3 is disposed in the opening 21. Here the sequence of the formation of the through holes and the disposition of the second substrate 3 in the opening 21 is not intended to be rigid. In another embodiment, the through holes 31 may be formed in the second substrate 3 after the second substrate 3 is disposed in the opening 21.

In the embodiment, the first substrate 2 may also be formed with a plurality of through holes 22, however, this is optional. It is worth mentioning that, likewise, the through holes 22 may be firstly formed in the first substrate 2, and then the second substrate 3 is disposed in the opening 21, or the through holes 22, 31 may be collectively formed in the first substrate 2 and the second substrate 3 after the second substrate 3 is disposed in the opening 21. Moreover, the through holes 22, 31 may be formed by, for example, mechanical drilling, laser drilling, or the other suitable method. In the other embodiment, the first substrate 2 may be further formed with a redistribution layer (RDL), however, this is optional.

Further, the through holes 22, 31 may be blind hole or buried hole. The structure and configuration may be adapted depending on different design requirements.

As shown in FIG. 1 and FIG. 2D, in the step S13, the adhesive layer 4 is formed between the first substrate 2 and the second substrate 3. The adhesive layer 4 may be, for example, adhesive, glue layer, conductive paste (such as, but not limited to, solder paste), plated metal, or the other suitable adhesive material. The adhesive layer 4 is used to fix the second substrate 3 in the opening 21 of the first substrate 2. It is worth mentioning that the through holes 22, 31 may be formed in the first substrate 2 and the second substrate 3 after the adhesive layer 4 is formed in the first place. It should be noted that the adhesive layer 4 is preferably to be applied to four sides of the second substrate 3 to avoid one of the four sides of the second substrate 3 being directly contacted the first substrate 2 to deteriorate the bonding strength.

Further, in the embodiment, the first substrate 2, the second substrate 3, and the adhesive layer 4 are substantially coplanar with each other. In other words, the surfaces (for example, upper surfaces and lower surfaces in FIG. 2D) of the first substrate 2, the second substrate 3, and the adhesive layer 4 are substantially on the same plane.

As shown in FIG. 1 and FIG. 2E, in the step S14, a bonding layer 5 is formed on the first substrate 2 and the second substrate 3. In the embodiment, the first substrate 2, the second substrate 3, and the adhesive layer 4 are substantially coplanar with each other, thereby allowing the bonding layer 5 to be coplanarly formed on the first substrate 2, the second substrate 3, and the adhesive layer 4. In other words, as the bonding layer 5 is disposed on the surfaces (for example, upper surfaces and lower surfaces in FIG. 2D) of the first substrate 2, the second substrate 3, and the adhesive layer 4, the bonding layer 5 is substantially formed to extend across the first substrate 2, the second substrate 3, and the adhesive layer 4 on the same plane. Moreover, in the embodiment, the bonding layer 5 may be further extended to the through holes 31 of the second substrate 3, however, this is optional.

It should be noted that the description of forming the bonding layer 5 on the first substrate 2 and the second substrate 3 indicates forming the bonding layer 5 on upper surfaces and lower surfaces of the first substrate 2 and the second substrate 3, the similar description hereafter is the same.

In the embodiment, the bonding layer 5 may be formed on the first substrate 2, the second substrate 3, and the adhesive layer 4 by, for example, a physical vapor deposition (PVD) process (such as, but not limited to, sputtering process). In another embodiment, the bonding layer may be formed on the first substrate 2 and the second substrate 3 by, for example, a chemical vapor deposition (CVD) process or a chemical plating process. It is worth mentioning that when the sputtering process is used to form the bonding layer 5 on the first substrate 2, the second substrate 3, and the adhesive layer 4, the material of the bonding layer 5 may be, for example, Ti or the other suitable material. On the other hand, when the CVD process or the chemical plating process is used to form the bonding layer 5 on the first substrate 2, the second substrate 3, and the adhesive layer 4, the material of the bonding layer 5 may be, for example, Ni or the other suitable material.

Therefore, since the bonding layer 5 is coplanarly formed on the first substrate 2, the second substrate 3, and the adhesive layer 4, the flatness and thickness uniformity of the bonding layer 5 may be greatly improved. As a result, the problem that the bonding layer is not present at the location of the adhesive layer as the bonding layer is formed prior to the adhesive layer is avoided, and the bonding strength between the first substrate 2 and the second substrate 3 is increased.

As shown in FIG. 1 and FIG. 2F, in the step S15, a metal layer 6 is formed on the bonding layer 5. In the embodiment, the metal layer may be, for example, a copper layer. The metal layer 6 may be formed on the bonding layer 5 by, for example, chemical plating process (which includes, but not limited to, the electroless copper plating process). In the embodiment, the metal layer 6 may be further formed in the through holes 31 of the second substrate 3 to form plated through hole (PTH) structures. It is worth mentioning that the metal layer 6 may be additionally disposed in the through holes 22 of the first substrate 2 and the through holes 31 of the second substrate 3 to form the PTH structures.

As shown in FIG. 1 and FIG. 2G, a mask layer 7 is formed on the metal layer 6 in advance. The mask layer 7 is used for forming the circuit pattern. The mask layer 7 may be, for example, a dry film which is a polymer resin reactive to ultraviolet, and is polymerized to protect the films lying underneath from being etched. Therefore, the area 71 of the mask layer 7 is, for example, the area where the light is not shined, and the area 72 of the mask layer 7 is, for example, the area where the light is shined.

As shown in FIG. 1 and FIG. 2H, the area 71 of the mask layer 7 is the area where the light is not shined, and thus the area 71 of the mask layer 7 is removed in the lithography process to expose the metal layer 6 lying underneath. The area 72 of the mask layer 7 is the area where the light is shined, and thus the area 72 is remained in the lithography process. Afterward, a metal layer 8 is formed in the area 71 where the mask layer 7 is removed. The metal layer 8 may be, for example, a copper layer, and may be formed on the metal layer 6 by the copper electroplating process.

As shown in FIG. 1 and FIG. 2I, in the step S16, the metal layer 8 is patterned to form the circuit layer 9. Lastly, the area 72 of the mask layer 7 is removed, and the metal layer 6 and the bonding layer 5 in the area 72 are removed by etching. As a result, the manufacturing of the circuit board 1 of the embodiment is completed.

In summary, the manufacturing method of the circuit board in the embodiment is featured by forming the adhesive layer 4 so as to bond the first substrate 2 (for example, a printed circuit board) and the second substrate 3 (for example, a ceramic substrate) first and then form the bonding layer 5 on the first substrate 2, the second substrate 3, and the adhesive layer 4. Since the bonding layer 5 and the metal layer 6 are not formed when the first substrate 2 is bonded with the second substrate 3 by the adhesive layer 4, the surfaces (upper surfaces or lower surfaces) of the first substrate 2, the second substrate 3, and the adhesive layer 4 are substantially coplanar with each other. As a result, the problem that the bonding layer 5 and metal layer 6 are not present at the location of the adhesive layer 4 as the bonding layer 5 and the metal layer 6 are formed prior to the adhesive layer 4 is avoided. In other words, the bonding layer 5 and the metal layer 6 may be coplanarly formed on the first substrate 2 and the second substrate 3, and the flatness and thickness uniformity of the circuit layer 9 which is patterned subsequentially may be increased so as to improve the reliability of the circuit board 1. Further, the first substrate 2 and the second substrate 3 are bonded together first and then the bonding layer 5 and the metal layer 6 are formed on the first substrate 2 and the second substrate 3, thus, the manufacturing process steps may be united so as to be carried out in one station without the need of carrying out each process step in different stations, and the total cost may be further decreased. Moreover, as the circuit layer 9 (circuit pattern) is formed across the first substrate 2 and the second substrate 3, the flatness and thickness uniformity of the circuit layer 9 is increased, thereby increasing the reliability of the circuit board 1 by employing this invention.

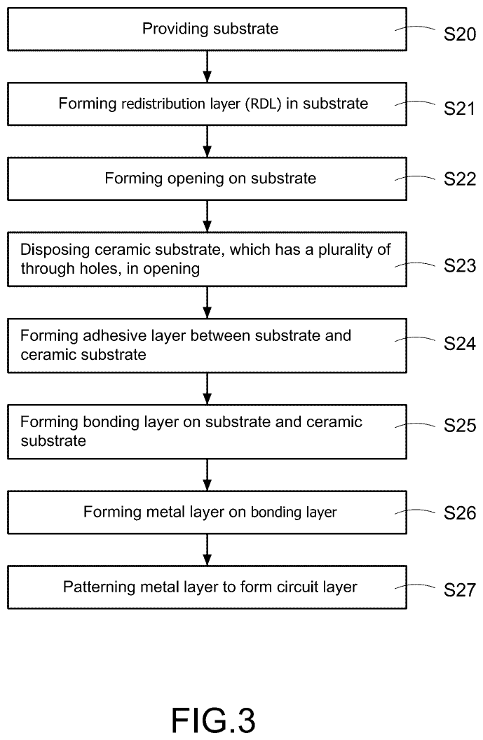

FIG. 3 is a flowchart of a second embodiment of the manufacturing method of the circuit board in the disclosure. As shown in FIG. 3, the second embodiment of the manufacturing method of the circuit board in the disclosure includes the step S20 to the step S27. The step S20 is carried out by providing a substrate. The step S21 is carried out by forming a redistribution (RDL) layer in the substrate. The step S22 is carried out by forming an opening in the substrate. The step S23 is carried out by disposing a ceramic substrate, which has a plurality of through holes, in the opening. The step S24 is carried out by forming an adhesive layer between the substrate and the ceramic substrate. The step S25 is carried out by forming a bonding layer on the substrate and the ceramic substrate. The step S26 is carried out by forming a metal layer on the bonding layer. The step S27 is carried out by patterning the metal layer to form a circuit layer.

The step S20, step S22, step S23, step S24, step S25, step S26, as well as step S27 are like the step S10 to the step 16 in the first embodiment, and here it is not intended to give details for brevity. The difference between the second embodiment and the first embodiment is that the second embodiment further includes the step of forming a redistribution layer in the substrate (the step S21).

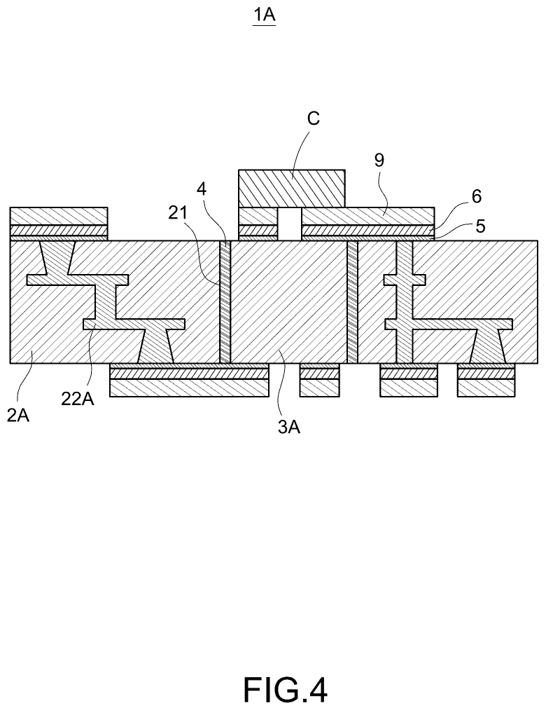

FIG. 4 is a schematic diagram of a circuit board 1A in the disclosure. As shown in FIG. 4, the redistribution layer 22A may be firstly formed in the substrate 2A. In other words, the redistribution layer 22A may be firstly formed in the substrate 2A before the substrate 2A is bonded with the ceramic substrate 3A. Further, after the circuit board 1A is manufactured, the redistribution layer 22A is connected to the circuit layer 9.

It is worth mentioning that the ceramic substrate 3A may or may not have a plurality of through holes. In the embodiment, the ceramic substrate 3A without the through holes is taken as an example, however, this example is not intended to be limitative. As described in the first embodiment, the ceramic substrate 3A may also have a plurality of through holes. For example, the through holes are firstly formed in the ceramic substrate 3A, and then the ceramic substrate 3A is disposed in the opening 21, or the through holes may be formed in the ceramic substrate 3A after the ceramic substrate 3A is disposed in the opening 21.

Further, likewise, the substrate 2A, the ceramic substrate 3A, and the adhesive layer 4 are substantially coplanar with each other, thereby allowing the bonding layer 5 to be coplanarly formed on the substrate 2A, the ceramic substrate 3A, and the adhesive layer 4. In other words, the bonding layer 5 is disposed on the surfaces (for example, upper surfaces and lower surfaces in FIG. 4) of the substrate 2A, the ceramic substrate 3A, and the adhesive layer 4, and thus they are substantially formed on the same plane.

Likewise, the bonding layer 5 may be formed on the substrate 2A, the ceramic substrate 3A, and the adhesive layer 4 by, for example, the PVD process (such as, but not limited to, sputtering process), or otherwise the bonding layer 5 may be formed on the substrate 2A and the ceramic substrate 3A by, for example, the CVD process or the chemical plating process. When the sputtering process is used to form the bonding layer 5 on the substrate 2A, the ceramic substrate 3A, and the adhesive layer 4, the material of the bonding layer 5 may be, for example, Ti or the other suitable material. On the other hand, when the CVD process or the chemical plating process is used to form the bonding layer 5 on the substrate 2A, the ceramic substrate 3A, and the adhesive layer 4, the material of the bonding layer 5 may be, for example, Ni or the other suitable material.

Moreover, likewise, the metal layer 6 is formed on the bonding layer 5. The metal layer may be, for example, a copper layer. The metal layer 6 may be formed on the bonding layer 5 by, for example, the chemical plating process (which includes, but not limited to, the electroless copper plating process).

Further, the chip C may be disposed on the circuit board 1A to be connected to the circuit layer 9. The types of the chip C is not to be limitative.

In summary, the manufacturing method of the circuit board in the embodiment may also avoid the problem that the bonding layer 5 and metal layer 6 are not present at the location of the adhesive layer 4 as the bonding layer 5 and the metal layer 6 are formed prior to the adhesive layer 4. In other words, the bonding layer 5 and the metal layer 6 may be coplanarly formed on the substrate 2A and the ceramic substrate 3A, and the flatness and thickness uniformity of the circuit layer 9 which is patterned subsequentially may be increased so as to improve the reliability of the circuit board 1A of the embodiment. Further, as the substrates 2A and 3A are bonded together and then the bonding layer 5 and the metal layer 6 are formed on the substrate 2 and the ceramic substrate 3A, the manufacturing process steps may be united so as to be carried out in one station without the need of carrying out each process step in different stations, and the total cost may be further decreased. Moreover, as the circuit layer 9 (circuit pattern) is formed across the first substrate 2 and the second substrate (ceramic substrate) 3, the flatness and thickness uniformity of the circuit layer 9 is increased, thereby increasing the reliability of the circuit board 1A.

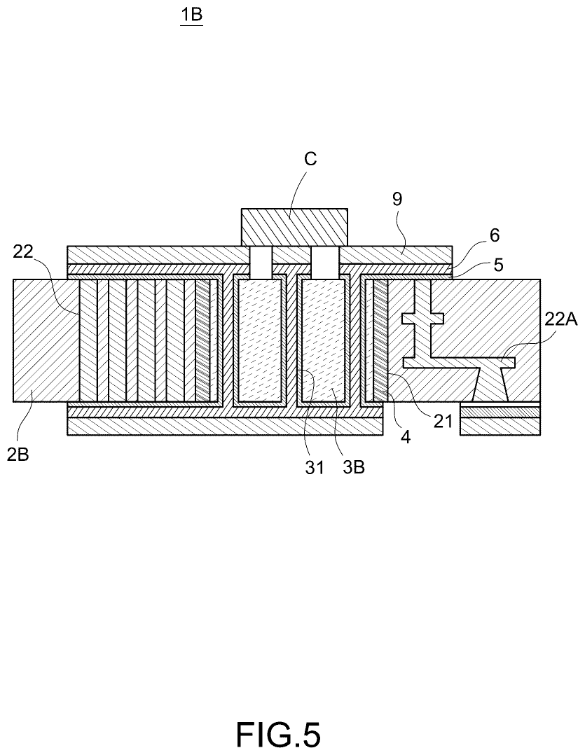

FIG. 5 is a schematic diagram of a circuit board 1B in the disclosure. In the embodiment, the circuit board 1B includes a substrate 2B, a ceramic substrate 3B, an adhesive layer 4, and a circuit layer 9. The substrate 2B has an opening 21. The ceramic substrate 3B is disposed in the opening 21 and has a plurality of through holes 31. The adhesive layer 4 is disposed between the substrate 2B and the ceramic substrate 3B. The circuit layer 9 is disposed on the substrate 2B and the ceramic substrate 3B. The substrate 2B, the ceramic substrate 3B, and the adhesive layer 4 are substantially coplanar with each other.

The differences between the circuit board 1B of this embodiment and the circuit boards 1, 1A of the aforementioned embodiments are that the substrate 2B has the through holes 22 and the RDL 22A, and the ceramic substrate 3B has the through holes 31. The through holes 22 of the substrate 2B and the through holes 31 of the ceramic substrate 3B may be, for example, used as the heat dissipating through hole to increase the heat dissipation efficiency of the circuit board 1B. Moreover, the through holes 22, 31 may be configured as blind holes or buried holes. The structure of the through holes 22, 31 may be adapted depending on different requirements.

It Is worth mentioning that the circuit board 1B of the embodiment may be manufactured by the manufacturing method of the first embodiment and the second embodiment.

In summary, the circuit board and the manufacturing method thereof in the disclosure is characterized in forming the bonding layer and the metal layer on the first substrate (for example, the printed circuit board substrate) and the second substrate (for example, the ceramic substrate) posterior to the step of bonding the first substrate with the second substrate by the adhesive layer. Since the bonding layer and the metal layer are not formed when the first substrate is bonded with the second substrate by the adhesive layer, the surfaces (upper surfaces or lower surfaces) of the first substrate, the second substrate, and the adhesive layer are substantially coplanar with each other. As a result, the problem of that the bonding layer is not present at the location of the adhesive layer as the bonding layer and the metal layer are formed prior to the adhesive layer is avoided. In other words, the bonding layer and the metal layer may be coplanarly formed on the first substrate and the second substrate, and the flatness and thickness uniformity of the circuit layer which is patterned subsequently may be increased so as to improve the reliability of the circuit board of the disclosure. Further, the first substrate and the second substrate are bonded together first and then the bonding layer and the metal layer are formed on the first substrate and the second substrate, thus, the manufacturing process steps may be united so as to be carried out in one station without the need of carrying out each process step in different stations, and the total cost may be further decreased. Moreover, as the circuit layer (circuit pattern) is formed across the first substrate and the second substrate, the flatness and thickness uniformity of the circuit layer is increased, thereby increasing the reliability of the circuit board.

While this disclosure has been described by means of specific embodiments, numerous modifications and variations may be made thereto by those skilled in the art without departing from the scope and spirit of this disclosure set forth in the claims.

What is claimed is:

1. A manufacturing method of a circuit board, the manufacturing method comprising:
providing a first substrate;
forming an opening in the first substrate;
disposing a second substrate, which comprises a plurality of through holes, in the opening;
forming an adhesive layer between the first substrate and the second substrate;
forming a bonding layer on the first substrate and the second substrate;
forming a metal layer on the bonding layer; and
patterning the metal layer to form a circuit layer.

2. The manufacturing method according to claim 1, wherein the step of disposing the second substrate in the opening further comprises:
forming the through holes in the second substrate before disposing the second substrate in the opening.

3. The manufacturing method according to claim 1, wherein the step of disposing the second substrate in the opening further comprises:
forming the through holes in the second substrate after disposing the second substrate in the opening,

4. The manufacturing method according to claim 1, wherein the step of forming the bonding layer on the first substrate and the second substrate further comprises:
coplanarly forming the bonding layer on the first substrate and the second substrate.

5. The manufacturing method according to claim 4, wherein the step of coplanarly forming the bonding layer on the first substrate and the second substrate further comprises:
forming, by a physical vapor deposition process, the bonding layer on the first substrate and the second substrate.

6. The manufacturing method according to claim 4, wherein the step of coplanarly forming the bonding layer on the first substrate and the second substrate further comprises:
forming, by a chemical vapor deposition process or a chemical plating process, the bonding layer on the first substrate and the second substrate.

7. The manufacturing method according to claim 1, wherein the step of providing the first substrate further comprises:
forming a redistribution layer in the first substrate.

8. The manufacturing method according to claim 1, wherein the step of forming the metal layer on the bonding layer further comprises:
forming, by a chemical plating process, the metal layer on the bonding layer.

9. A manufacturing method of a circuit board, the manufacturing method comprising:
providing a substrate;
forming a redistribution layer in the substrate;
forming an opening in the substrate;
disposing a ceramic substrate, which comprises a plurality of through holes, in the opening;
forming an adhesive layer between the substrate and the ceramic substrate;
forming a bonding layer on the substrate and the ceramic substrate;
forming a metal layer on the bonding layer; and
patterning the metal layer to form a circuit layer.

10. The manufacturing method according to claim 9, wherein the step of disposing the ceramic substrate in the opening further comprises:
forming the through holes in the second substrate before disposing the second substrate in the opening.

11. The manufacturing method according to claim 9, wherein the step of disposing the ceramic substrate in the opening further comprises:
forming the through holes in the second substrate after disposing the second substrate in the opening.

12. The manufacturing method according to claim 9, wherein the step of forming the bonding layer on the substrate and the ceramic substrate further comprises:
coplanarly forming the bonding layer on the substrate and the ceramic substrate.

13. The manufacturing method according to claim 12, wherein the step of coplanarly forming the bonding layer on the substrate and the ceramic substrate further comprises:
forming, by a physical vapor deposition process, the bonding layer on the substrate and the ceramic substrate.

14. The manufacturing method according to claim 12, wherein the step of coplanarly forming the bonding layer on the substrate and the ceramic substrate further comprises:
forming, by a chemical vapor deposition process or a chemical plating process, the bonding layer on the substrate and the ceramic substrate.

15. The manufacturing method according to claim 9, wherein the step of forming the metal layer on the bonding layer further comprises:
forming, by a chemical plating process, the metal layer on the bonding layer.

16. A circuit board, comprising:
a substrate, comprising an opening;
a ceramic substrate, disposed in the opening, and comprising a plurality of through holes;
an adhesive layer, disposed between the substrate and the ceramic substrate; and
a circuit layer, disposed on the substrate and the ceramic substrate, wherein the substrate, the ceramic substrate, and the adhesive layer are substantially coplanar with each other.

17. The circuit board according to claim 16, wherein the substrate further comprises a redistribution layer connected to the circuit layer.

18. The circuit board according to claim 16, further comprising:
a bonding layer, disposed between the circuit layer and the substrate and disposed between the circuit layer and the ceramic substrate.

19. The circuit board according to claim 18, wherein the bonding layer is coplanarly extended across the substrate, the ceramic substrate, and the adhesive layer.

20. The circuit board according to claim 18, wherein the bonding layer is extended to the through holes.
